(19) United States
(12) Patent Application Publication
(10) Pub. No.: US 2024/0019468 A1
(43) Pub. Date: Jan. 18, 2024

(54) HIGH-RESOLUTION ELECTRICAL MEASUREMENT DATA PROCESSING

(71) Applicant: NEUVILLE GRID DATA MANAGEMENT LIMITED, London (GB)

(72) Inventors: Maitreyee DEY, LONDON (GB); Soumya Prakash RANA, London (GB)

(21) Appl. No.: 18/248,519

(22) PCT Filed: Oct. 8, 2021
(86) PCT No.: PCT/GB2021/052613

§ 371 Date: Apr. 10, 2023

(30) Foreign Application Priority Data
Oct. 9, 2020 (GB) 2016025.5

(51) Int. Cl. G01R 22/06

(52) U.S. Cl. CPC G01R 22/061

(57) ABSTRACT

A method of processing high resolution electrical measurement data is disclosed including obtaining high resolution electrical measurement data related to time series data of a parameter measured from an electrical power grid system. The time series data comprises a first data points set transformed to feature vector format data where the time series data is grouped into a plurality of datasets, each dataset representing a subset of the first data points set. A statistical data clustering scheme is performed to generate distinct cluster patterns from the feature vector format data comprising a first cluster relating to a first electrical trend, a second cluster relating to a second, different electrical trend, and an outlier data pattern that is part of the first or second cluster. The outlier data pattern is far from its respective cluster centre. An anomalous event detection is based at least in part on the outlier data.

### FIELD OF THE INVENTION

The invention provides methods and apparatus for processing of measurement data related to an electrical power grid or other electrical apparatus by using machine learning techniques and providing anomalous event detection from the electrical measurement data.

### BACKGROUND

Stopping climate change motivates implementation of renewable energy sources such as wind and solar with much smaller carbon footprints than non-renewable sources. However, the behaviour of renewable sources may be irregular and can bring challenges for consistent operation in power distribution systems. Utility-scale (>1 MW) solar farm owners may suffer from significant plant failure rates, reduced equipment life, unplanned outages, and replacement overheads. These problems can be countered through better condition monitoring data collection and knowledge discovery to automatically understand issues and predict problems before they occur.

Monitoring tools can provide more granular and higher accuracy data capture together with precise timing information. However, there can be problems in the capability to process the data and detect anomalous behaviour, faults and failure modes.

### SUMMARY OF INVENTION

According to a first aspect, the present invention provides a method of processing high resolution electrical measurement data according to claim 1. According to a second aspect, the present invention provides a system for processing high resolution electrical measurement data according to appended claim 15. Further optional features are provided in the appended dependent claims.

The inventors of the present invention have determined that high resolution data that may have been received from a sensor such as micro-synchrophasor measurement unit (μPMU) data can be collected and analysed alongside power quality measurement data that may have been received from another sensor such as a power quality monitor (PQM), both the μPMU and PQM located proximal to a power generating array such as a photovoltaic cell (solar) farm, and one or more machine learning techniques can be used for processing of the data for remote and automatic anomaly detection. Resolution can determine the precision of a measurement. High resolution data can be measured and will provide high precision. The variation to the resolution can affect the performance and processing (time and computational complexity) but the examples described herein may be adapted to work with different resolution data and the invention has been found to provide particularly effective results at high resolutions where information may be obtained, for example, from a micro-synchrophasor measurement unit.

The micro-synchrophasor measurement unit and power quality monitor may be integrated into a grid data unit that can provide high-resolution, high-precision, time-stamped data. The micro-synchrophasor may be configured to operate in the frequency-domain to process an electrical signal and collect a first set of data points; and the power quality monitor may be configured to operate in the time-domain to process the electrical signal and collect a second set of data points. The grid data unit may be configured to apply the same synchronised timestamp to the collected first and second sets of data points. A time-series database may receive the high resolution data, preferably via a secure telemetry. Time-series databases are better suited to such high volume measurements than relational databases. The database may be a data lake that can contain structured or unstructured data. This more efficient and effective grid data unit apparatus matches the volume (prospectively quadrillions of data-points amounting to petabytes) and rate of data collection with suitable handling and storage capacities. While the grid data hardware and database/data lake could operate independent of the other, together they provide an integrated solution offering superior performance with a reduced amount of equipment required.

The machine learning techniques can include data-driven unsupervised learning of data received from a micro-syncrophasor unit to detect an anomalous electrical event from the solar farm which may be connected to a power distribution system.

The machine learning techniques may use a partitioning based clustering method such as Clustering Large Applications based upon Randomised Search (CLARANS) to process the large amount of data that may be generated by the grid data unit. The clustering can identify clusters of data and distinctly separate data patterns occurring in the data. Abnormalities or outlier events can be identifiable from the clustered data which may be graphically represented and subsequently analysed automatically. Power quality monitor data from the power quality monitor device which may have been collected less frequently than the data from the micro-synchrophasor measurement unit can be used to validate the detected outlier events occurring in the clustered data as the time stamping of the data is consistent between the μPMU data and the PQM. The voltage and current phasor data may then be analyzed further to determine more information relating to the outlier event such as whether there was a fault event such as a voltage dip event in a particular window of time.

### BRIEF DESCRIPTION OF THE DRAWINGS

Systems and methods are described in detail below, by way of example only, with reference to the accompanying drawings in which:

FIG. 1 shows a schematic diagram of a data collection and processing system according to an example;

FIG. 2 shows a schematic diagram of a data collection unit that may be used in the example of FIG. 1;

FIG. 3 shows a method of data collection and processing according to an example;

FIG. 4 shows a data set transformation that may be performed according to an example;

FIG. 5 shows a method for processing high-resolution electrical measurement data regarding an electrical power grid according to an example;

FIG. 6 shows a graphical representation of clustering outcomes in an example experiment; and

FIG. 7 shows a graphical representation of voltage dips of the μPMU data on the tested day according to the example experiment.

### DETAILED DESCRIPTION

Renewable power sources such as solar panels that work by absorbing sunlight with photovoltaic cells, generating direct current (DC) energy and then converting it to usable alternating current (AC) energy with the help of inverter technology. AC energy then flows through the electrical busbar and is distributed accordingly. Electrical characteristics or parameters of generated power from the power source and load may be collected and processed.

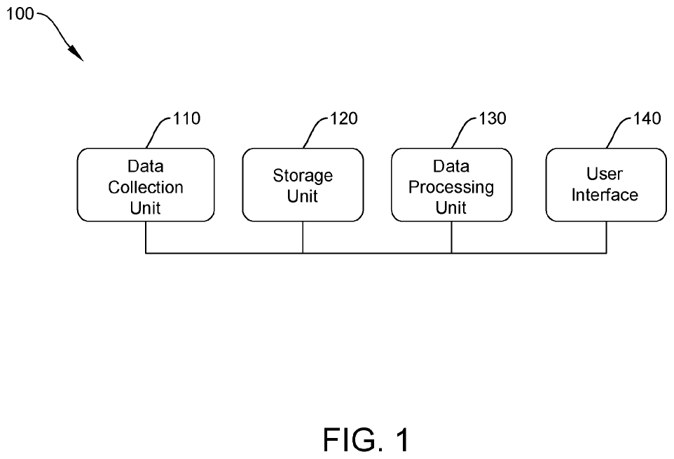

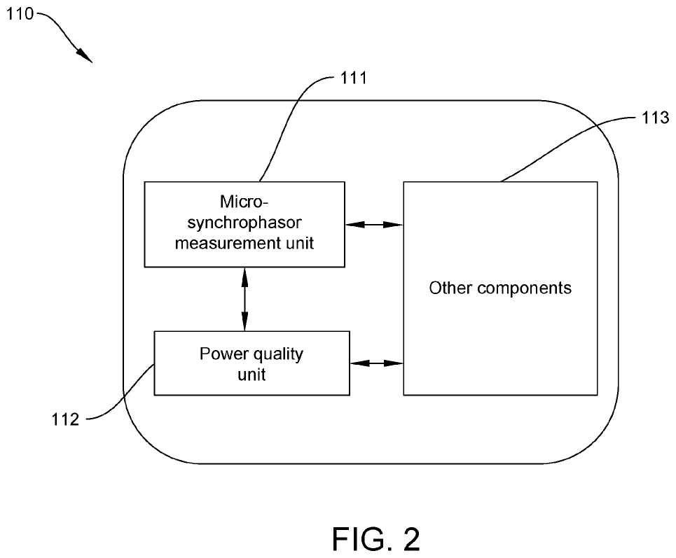

Referring to FIG. 1, in an example, a data collection and processing system 100 comprises a data collection unit 110, a storage unit 120, a data processing unit 130, and a user interface 140. The data collection unit 110 is described in more detail below with reference to FIG. 2. The storage unit 120 may be in a server that is located remote from the data collection unit 110, for example, in the cloud. The processing unit 130 may also be located remote from the data collection unit and can process time-series data that is collected by the data collection unit 110 and received by the storage unit 120. The processing unit 130 may be distributed across a number of devices to carry out the processing functionality or there may be a plurality of processing modules are different locations. The processing may include cleaning the data from the data collection unit to remove entries that include missing data, compressing or sampling the time series data, and transforming the data into a vector representation that represents the time series data into a plurality of data sets representing a subset of the time series data. The processing by the processor unit 130 may further include performing a clustering technique to segregate the data into two or more clusters and generating a representation of the segregated data. The user interface 140 may display information relating to the generated representation of the segregated data. The clustered data which is a segregated form of the data that is generated according to the clustering technique may include outlier data that is part of a cluster but that is relatively far from the medoid of the particular cluster that it is part of. Such outlier data may be furthest from or far removed from a particular inter-cluster medoid or centroid or centre of the cluster and can be identifiable as outlier data manually through inspection of the generated representation or automatically using thresholds above or below which represent outliers. The inter-cluster medoid or centroid may be representative of the higher density data patterns and the centre of the cluster.

The outlier data can be related to an anomalous event. Validation of the outlier data may be carried out by identifying time and magnitude information of the outlier data from the vector representation and mapping with time series data previously obtained from the grid data unit to precisely identify the outlier data and detect a related anomalous event. The user interface 140 provides a means for user interaction with the various units 110,120,130 and each of the units may be provided with its own user interface or a single user interface may interact with one or more of the units 110,120,130. The user interface may interact with a user, for example, by conveying data to a user such as by displaying visual images, graphs, results, and by receiving user input. The system may be part of a power generation system and network and can provide highly accurate information on the state of the generating equipment and power network. Such information can be used to make operational decisions to maximise utilization of the power generation plant. In some examples, the system is used to optimise the utilization of solar farms, wind turbines, electrical loads, transmission & distribution systems, or energy storage plants, or other electrical facilities.

Referring to FIG. 2, an example of the data collection unit 110 is described in more detail. In the example, the data collection unit is a grid data unit (GDU) 110 that can be installed at a solar panel site to collect electrical characteristics such as, current, and voltage of generated power from a photovoltaic cell (PV). A micro-synchrophasor (μPMU or microPMU) instrument 111 is incorporated into the GDU 110. The microPMU is a high-resolution variant of phasor measurement units (PMU). Each GDU may further comprise a power quality monitor (PQM) unit 112. The μPMU instrument 111 and the PQM unit 112 may work as an operative pair of signal analysers. The GDU 110 provides mechanical protection, instrument power, and telecoms equipment for data backhaul which can be shared by the μPMU instrument 111 and the PQM 112. Alternatively, each of the μPMU and the PQM has its own separate and not shared power supply, data storage and telemetry equipment. Furthermore, the GDU 110 may comprise other components 113 that may include a Global Positioning System (GPS) receiver for precision timestamping to sub-100 ns, solid-state memory for data-buffering and secure bidirectional 3G/4G cellular data telemetry equipment with the twice-per-cycle (100/120 Hz) data-reporting rate. Waveform A/D conversion occurs at 4 MHz with a sampling frequency of 25.6 kHz, disciplined by a GPS clock; for each half cycle of the voltage frequency (50 Hz in UK), voltage and current phasors are calculated, resulting in a 100 Hz data-reporting rate. This can be subsequently down-sampled where necessary into a data-rate required to suit the analysis being performed, by use of standard post-processing techniques. The phasor amplitude and angle accuracies of the μPMU instrument may be +/−0.05% and +/−0.01° respectively, producing a total vector error of +/−0.01%, although practical measurement uncertainty is determined by the upstream voltage and current transducers.

The μPMU 111 operates in the frequency domain and is used to collect voltage and current phasor measurement data for each half cycle at 10 milliseconds reporting periods (100 Hz in the UK). It may be configured to process an electrical signal and collect a first set of data points. It records the measurement of data with a time stamp and the measurement data may be one or more of: three phase voltages, three phase voltage angles, three phase current, three phase current angles, centre frequency offset, c37 frequency, fundamental power, fundamental apparent power, fundamental of reactive power global positioning system, latitude, longitude. The PQM 112 may be configured to operate in the time-domain to process the electrical signal and collect a second set of data points. It may provide a power quality function including an array of high-accuracy measurements according to the IEC 61000-4-30 Ed 3 Class A standard plus supra-harmonics in the 2-150 kHz range. The PQM 112 may have a lower time resolution of data being collected, for example, every 1 minute, and can be configured to send an alert to a user when an anomalous event such as a voltage sag or flicker is detected. The GDU 110 may be configured to apply the same synchronised timestamp to the collected first and second sets of data points. One-day data from the μPMU 111 can include each minute files that consist of six thousand rows representing each 10 milliseconds of data. Therefore, the measurement data will be a high time resolution and can include 8.64 million data points in a single day for each parameter. International patent application No. PCT/GB2019/051413 describes the use of a grid data unit including μPMUs and PQMs for sensing, monitoring and collecting electrical data and the subject matter is incorporated herein.

The amount of solar data collected by the grid data unit and particularly the μPMU 111 can be so large, fast, complex (provides several power parameters related to solar farm) that it may be difficult to process using traditional methods or manual analysis. However, irregular (or, abnormal) electrical characteristics of generated power from a PV brings challenges relating to consistent operation in power distribution systems, significant plant failure, reduction in equipment life, unplanned outages, and increase in the replacement overheads. In addition to the increasing velocities and varieties of electrical parameters, solar and wind farm data stream flows are unpredictable due to the sudden environmental changes (occur often) where magnitudes vary greatly, and can damage associated electrical equipment. Also, it can be difficult to link, match, cleanse and transform solar data across systems to find correlation between events and hierarchies. Hence, it is challenging to understand electrical power (and related parameter) trends and how to manage daily or regularly, seasonal and event-triggered peak data loads for maintaining solar farms, wind turbines, electrical loads, transmission & distribution systems, energy storage plants, or other electrical facilities.

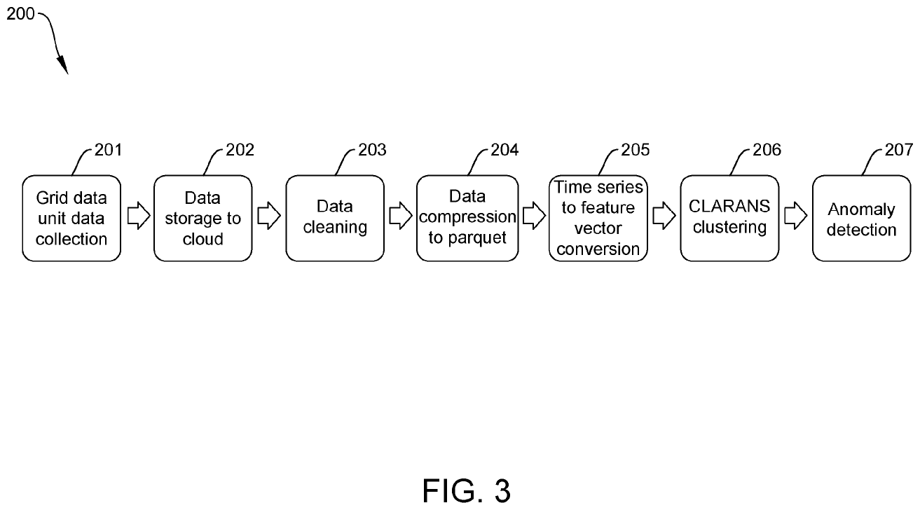

FIG. 3 shows a method of data collection and processing according to an example that may use the system such as that discussed in relation to FIG. 1. At 201, data is monitored and collected by a sensing unit such as the grid data unit described in relation to FIG. 2. Such data may relate to a characteristic of an electrical signal that has been generated from an electrical source which may be a renewable energy source such as a PV systems. The characteristic may include one or more of voltage, current and frequency. In particular, the characteristic can be three phase voltages, three phase voltage angles, three phase current, three phase current angles, centre frequency offset, c37 frequency, fundamental power, fundamental apparent power, and/or fundamental of reactive power global positioning system, latitude, longitude.

The characteristic of the electrical signal is monitored and data relating to the characteristic is collected at reporting periods. In an example, and as mentioned in relation to the μPMU in FIG. 2, data is collected for each half cycle at 10 millisecond reporting periods. It will be appreciated that, instead of 10 milliseconds, alternative reporting periods may be provided to collect high time resolution data. Data from the PQM may also be collected regularly and may be at a different lower time resolution to the data from the μPMU. The electrical signal from the power source is simultaneously monitored in the frequency-domain via the μPMU and in the time-domain using the PQM to collect time-domain data points and frequency domain data points. A congruent timestamp is applied to the collected time-domain data points and frequency-domain data points. In some examples, the timestamp applied to the collected time-domain data points and frequency-domain data points is derived by the same method. As each characteristic can be monitored and collected separately, each characteristic that is being monitored every 10 milliseconds can result in 8.64 million data points of raw data collected in a single day for that characteristic.

At 202, raw data may be sent to a server that is located remote to the grid data unit for storage. The high resolution data from the μPMU may then be further processed. The processing of data can include: (a) handling the data and its storage; and (b) automatic data processing for electrical trend finding. As a voltage source converter and its behavior is the heart of PV solar farm, the voltage has been considered for identifying the data irregularity (or abnormality) processing the solar data in an example for ease of explanation although it will be appreciated that the processing can be carried out also for other characteristics that are collected.

(a) Handling the Data and its Storage:

At 203, the raw data may be cleaned in that any time stamped data that is missing from the raw data is removed from the data set. This can reduce the size of the data set by removing missing data that would not provide any useful information from subsequent processing. The raw data from the μPMU can be large in volume and unstructured in nature. At 204, lossless data compression can be carried out. In an example a column based storage format is used as oppose to a row based storage format (such as CSV). An example of a column based storage format is the Apache Parquet (an open source file) format which can be used to create a data lake or data warehouse which offers compressed, an efficient columnar solar data representation for further processing. A substantial reduction in data set size can be obtained using Apache Parquet and in one example an 83% reduction in file size may be achieved compared to a row based storage format such as CSV. It will be appreciated that the cleaning and compressing of the raw data can provide advantages but may not be needed for automatic electrical trend finding.

(b) Automatic Data Processing for Electrical Trend Finding

Manual division and annotation of the data is too resource-intensive and difficult if not impossible while looking for anomalies (or irregular data behavior). Thus, the goal specifies here to separate two groups: regular/normal electrical trend, and irregular electrical trends. The best practice to achieve this goal is to create and map statistical algorithms like, clustering. By keeping in mind the fast processing and decision making, a clustering approach can be used based on CLARANS (Clustering Large Applications based on RANdomized Search). Compared to other clustering approaches, it has been found that the randomized search and the randomized selection of samples from the input data that is a property of CLARANS provides an effective and efficient technique where there is a large amount of data such as from a phasor measurement unit (PMU).

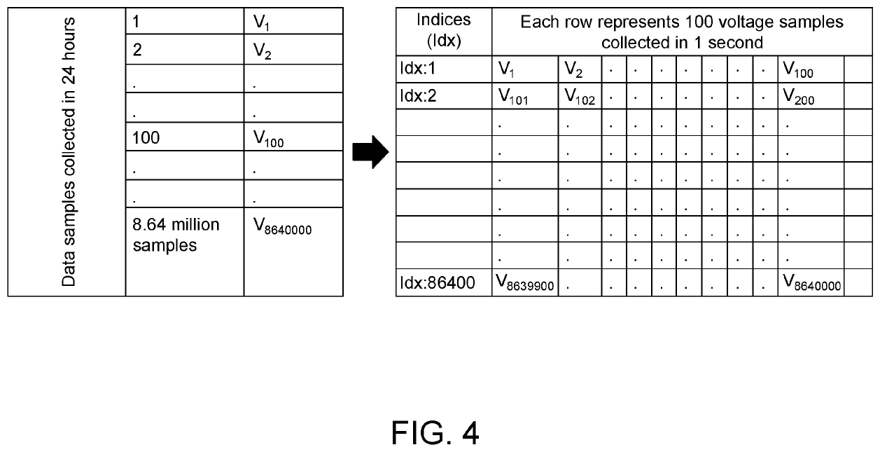

At 205, dataset transformation or conversion can be executed and the selection of the extent of the transformation will then affect the CLARANS clustering as this data will be analysed using CLARANS. An example of the transformation is shown in FIG. 4 where the data set containing 8.64 million time series data points of collected voltage values in 24 hours by the μPMU is transformed into a feature vector table with 86400 indices Idx and each row representing 100 voltage samples collected in 1 second. For example, the first row which relates to Idx:1 contains voltage values V₁ to V₁₀₀. The second row which relates to Idx:2 contains voltage values V₁₀₁ to V₂₀₀ and so on up to a final row which relates to Idx:86400 contains V₈₆₃₉₉₀₀ to V₈₆₄₀₀₀₀. It will be appreciated that different numbers of indices and number of voltage values per row may be selected but the transformation as selected in FIG. 4 is found to be effective for operation with CLARANS.

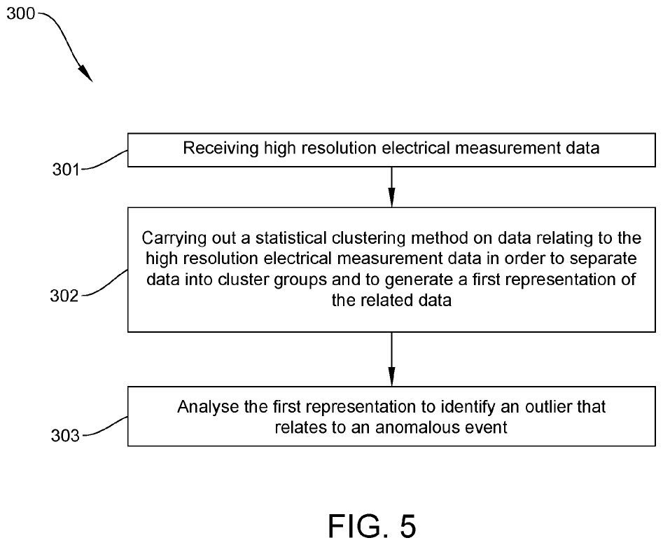

At 206, a clustering technique such as CLARANS can be carried out on the transformed dataset. Referring to FIG. 5, an example process that can be carried out includes, at 301, receiving high resolution electrical measurement data that is in a converted feature vector data format including a plurality of rows each containing a subset of the data (as generated in 205, for example). At 302, statistical clustering is carried out on the converted feature vector data from the high resolution electrical raw measurement data in order to separate data into distinct cluster groups. A first group may comprise a group of similar electrical trends (magnitude) and a second group may comprise a group of different electrical trends separated from the first group. Each cluster group has a plurality of data points, each corresponding to a pattern derived from the clustering technique performed on a row (eg. Idx of FIG. 4) of the feature vector table. Each cluster group will have a similar pattern which in this example relates to similar electrical trends. Each of the first and second cluster groups may also comprise one or more data points or patterns that are far removed or furthest from a centroid or medoid of a respective cluster group and such a data point can be identifiable as an outlier. Both groups may have their own outliers but do not share the same outlier as each outlier is part one particular cluster based on its pattern. A first representation may be generated of the clustered groups. At 303, the first representation can be analysed to identify an outlier that relates to an anomalous event. Although CLARANS is known, its use with high resolution electrical measurement data in the field of electrical energy generation and distribution systems can provide advantages in the field such as improvements in processing speed particularly for big data related to high resolution electrical measurement data from an apparatus such as a micro-synchrophasor or phasor measurement unit. CLARANS calculates two values, the local minima and maximum neighbour. The higher the value of the latter, the closer that CLARANS will be to other partitioning methods such as partitioning around medoids (PAM) and the longer it will take to perform each search of the local minima. This is an advantage because the quality of the local minima is higher, and a smaller number of local minima are discovered returning a best local optimal as the final result. CLARANS can select a medoid from a row of the feature vector table randomly before iterations are carried out in accordance with the conventional CLARANS technique.

An example of the application of the CLARANS clustering technique is described in more detail below in relation to the data set shown in FIG. 4:

### Input Parameters:

a) amount of iterations for solving the problem (experimentally selected 100 in our case)
b) the maximum number of neighbors/behavior pattern examined: percentage of neighbors×size (number of rows in transformed dataset, 1)

=(0.001%×86400)=|86.4|=86
c) the goal specifies here to separate two cluster groups that may relate to different electrical trends, thus the number of clusters we are looking for is two (initial random medoids will be 2).

Processing:
1. iteration i=1 to 100
2. minimum distance using Euclidean cost=0;
3. optimal medoids=0;
4. Now 2 random data points are selected as current medoids and clusters are formed using these data points where Euclidean distance is used to find the nearest medoid to form clusters.
   a. iteration j=1: j⇐86
   b. A random current medoid is selected and a random candidate (random neighbor) datapoint is selected for replacement with current medoid.
   c. If the replacement of candidate datapoint yields a lower Total Cost (which is the summation of distances between all the points in the clusters with their respective medoids) than the current medoid then the replacement is made. If replacement is done, then j is not incremented otherwise j=j+1.
5. Once j>86, then the current medoids are taken and their Total Cost is compared with minimum cost. If the Total Cost is less then minimum cost, then the Best Node is updated as the current medoids.
6. i is incremented afterwards and if it is greater than 100, then the Best Node is given as output otherwise whole process is repeated.

With the clustering technique, the high resolution electrical measurement data can be separated into clustered data that include a first cluster representing a first electrical trend and a second cluster representing an another electrical trend. In other examples, there may be more clusters to segregate the high resolution electrical measurement data.

Referring back to FIG. 3, at 207, the clustered data that is generated can be provided as a first representation in a graphical format for inspection of anomaly detection. The first representation may contain outlier data that is indicative of an anomalous event relating to the collected electrical data and the outlier event information can be identifiable from the representation by inspection. Alternatively or additionally, a threshold may be set to automatically determine whether the clustered information includes outlier data. For example, if the clustered data value is below or above a value by a certain percentage, for example, six percent, this can be indicative of the data being outlier data.

Validation may then occur given that the electrical signal received by the μPMU during a day was also collected by a PQM. The detected outlier events from the clustered data can be validated by mapping or correlating the PQM data which would have generated an alert when an anomalous event had been detected. The alert may include graphical representation of the PQM data at a high resolution showing the anomalous event.

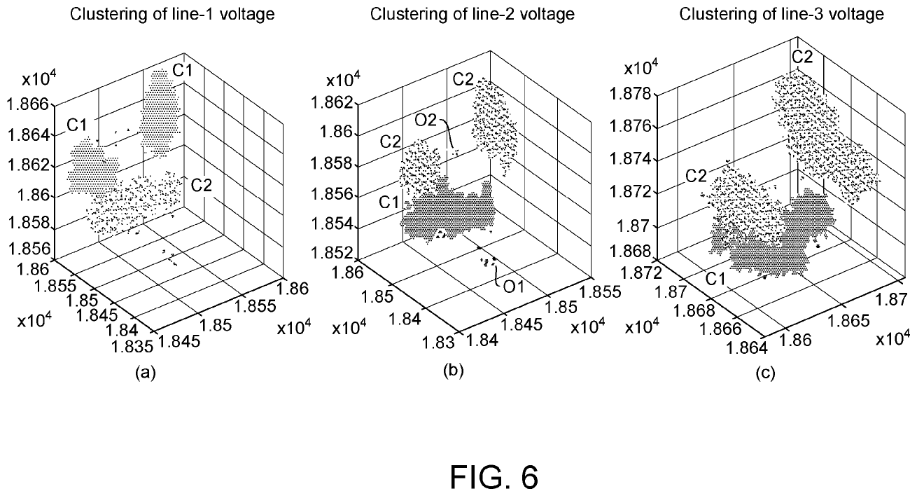

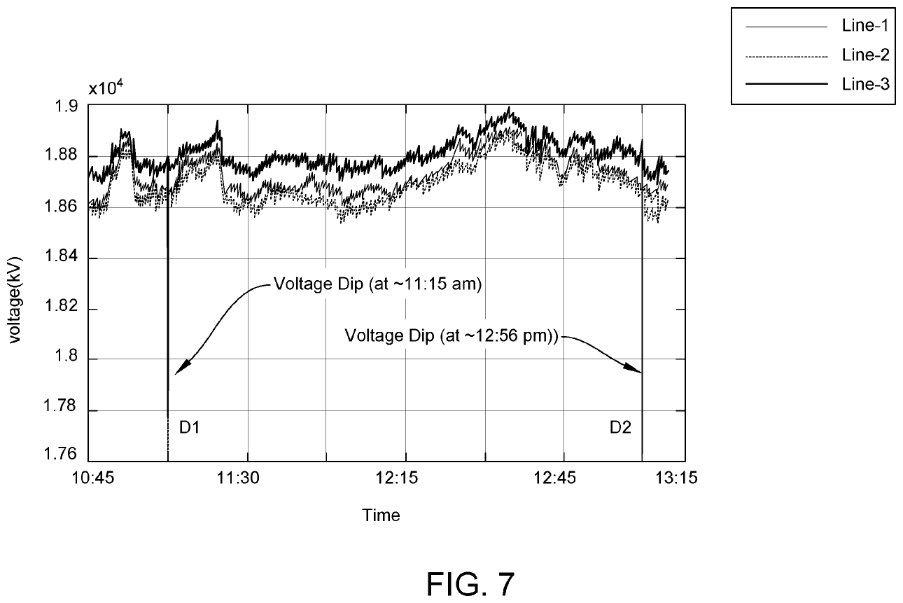

The clustering approach is now described according to an example experiment. In the example, the clustering approach has been experimented on three-phase voltage phasor data for 10 consecutive days (1May-10May 2020) to categorize its functional behavior and detect anomalies on the power distribution system. Each day, 8.64 million voltage phasor data points are gathered per phase. The results have been shown in FIG. 6 for 1May 2020. FIG. 6 presents the CLARANS outcomes of the line-1 (first phase), line-2 (second phase), and line-3 (third phase) voltages. From this figure it has been seen that the shape of both clusters in each figure are spherical each having a centre, thus depicting that a partitioning based method should work well to separate data patterns distinctly. FIGS. 6(a), 6(b), and 6(c) shows the line-1 patterns, line-2 patterns, and line-3 patterns respectively where the outliers are clearly visible in two distinct cluster types C1 (shown in a first shade for explanation purposes) and C2 (shown in a second shade). The outliers are part of cluster C1 or C2 but sufficiently far removed from the higher density cluster centre. With reference to FIG. 6(b), for example, outliers O1 and O2 are shown with outlier O1 being part of cluster C1 but far removed and outlier O2 being part of cluster C2 but far removed. This clustering causes the data to be grouped based on the magnitude variation throughout the day, where, in the example shown, one group comprises voltage magnitudes between ˜1.85 to ˜1.86 kV and the other group contains ˜1.87 to ˜1.88 kV respectively. The detected outlier events from the clustered data have been validated by the power quality measurement data and the abrupt event examples are shown in the FIG. 7. FIG. 7 is a window showing 1.5 hours of data, where the exact voltage dip event along with its time and magnitude is displayed. It has found that the voltage dip (˜11.15 am and ˜12.56 pm) occurred two times D1, D2 during this period and reaches a magnitude of 1.76 kV, captured precisely by the clustering approach. It can be seen that the clustering approach as described can provide useful performance grouping of high-resolution μPMU data for outlier detection.

1. Method for processing high resolution electrical measurement data, comprising:
obtaining high resolution electrical measurement data related to time series data of an electrical or other parameter measured from an electrical power grid system or other electrical apparatus, wherein the time series data comprises a first set of data points;
transforming the time series data to feature vector format data where the time series data is grouped into a plurality of datasets, each dataset representing a subset of the first set of data points;
carrying out a statistical data clustering scheme to generate distinct cluster patterns as clustered data from the feature vector format data, the clustered data comprising a first cluster relating to a first electrical trend and a second cluster relating to a second electrical trend which is different from the first electrical trend, wherein the clustered data comprises an outlier data pattern that is part of either the first or second cluster, and the outlier data pattern is far from its respective cluster centre; and
detecting an anomalous event based at least in part on the outlier data.

2. The method of claim 1, wherein the statistical clustering scheme is an unsupervised machine learning technique.

3. The method of claim 1, wherein the statistical clustering scheme is a partitioning based clustering method.

4. The method of claim 1, wherein the statistical clustering scheme is Clustering Large Applications based on Randomised Search, CLARANS.

5. The method of claim 1, wherein clustered data is generated as a first graphical representation.

6. The method of claim 1, further comprising identifying the outlier data, wherein the outlier data is identified automatically by comparing a value of the outlier data with a threshold.

7. The method of claim 1, further comprising compressing the time series data of the electrical parameter measured in an electrical power grid prior to obtaining.

8. The method of claim 7, wherein the compressing comprises lossless data compression in a column based storage format.

9. The method of claim 8, wherein the lossless data compression is in the Apache Parquet format.

10. The method of claim 1, wherein the high resolution electrical measurement data is measured by a micro-synchrophasor unit located in the electrical power grid system and operating in the frequency domain.

11. The method of claim 1, wherein a power quality monitor operates in the time-domain and generates a second set of data points of the electrical parameter measured from an electrical power grid system with synchronised time stamps relative to the first set of data points.

12. The method of claim 11, further comprising validating the clustered outlier data by mapping the outlier data with the second set of data points from the power quality monitor.

13. The method of claim 1, wherein the detecting further comprises determining further information relating to the outlier data including whether there is a fault event in a particular window of time.

14. The method of claim 1, wherein the electricity power grid system includes at least one of: solar farm, wind turbine, electrical load, transmission & distribution system, or energy storage plant, or other electrical facility.

15. System for processing high resolution electrical measurement data, comprising a processing unit operable to:
obtain high resolution electrical measurement data related to time series data of an electrical or other parameter measured from an electrical power grid system, wherein the time series data comprises a first set of data points;
transform the time series data to feature vector format data where the time series data is grouped into a plurality of datasets, each dataset representing a subset of the first set of data points;
carry out a statistical data clustering scheme to generate distinct cluster patterns from the feature vector format data comprising a first cluster type relating to a first electrical trend, a second cluster type relating to a second or different electrical trend, and outlier data that forms part of the first or second cluster type and is far from an inter-cluster medoid of the respective cluster type of which it is part; and
detect an anomalous event based at least in part on the outlier data.

16. The system of claim 15, wherein the statistical clustering scheme is an unsupervised machine learning technique.

17. The system of claim 15, wherein the statistical clustering scheme is a partitioning based clustering method.

18. The system of claim 15, wherein the statistical clustering scheme is Clustering Large Applications based on Randomised Search, CLARANS.

19. The system of claim 15, wherein clustered data is generated as a first graphical representation, and the system further comprises a display unit to display the graphical representation.

20. The system of claim 15, wherein the processing unit is operable to identify the outlier data, wherein the outlier data is identified automatically by comparing a value of the outlier data with a threshold.

21. The system of claim 15, wherein the processing unit is operable to compress the time series data of the electrical parameter measured or other measured value taken from an electrical apparatus such as the power grid prior to obtaining.

22. The system of claim 21, wherein the compressing comprises lossless data compression in a column based storage format.

23. The system of claim 22, wherein the lossless data compression is in the Apache Parquet format.

24. The system of claim 15, further comprising a micro-synchrophasor or phasor measurement unit that is operable in the frequency domain, wherein high resolution electrical phasor measurement data is measurable by the micro-synchrophasor measurement unit.

25. The system of claim 15, further comprising a power quality monitor operable in the time-domain and operable to generate a second set of data points of the electrical parameter measured from an electrical power grid system, wherein the second set of data points comprise the same synchronised time stamp with the first set of data points.

26. The system of claim 25, further comprising a micro-synchrophasor or phasor measurement unit that is operable in the frequency domain, wherein high resolution electrical phasor measurement data is measurable by the micro-synchrophasor measurement unit, and wherein the micro-synchrophasor measurement unit and the power quality monitor are integrated into grid data unit and operate as an operative pair of signal analysers.

27. The system of claim 25, wherein the processing unit is operable to validate the clustered outlier data by mapping the outlier data with the second set of data points from the power quality monitor.

28. The system of claim 15, wherein the detecting further comprises determining further information relating to the outlier data including whether there is a fault event in a particular window of time.

29. The system of claim 15, wherein the electricity power grid system includes at least one of: solar farm, wind turbine, electrical load, transmission & distribution system, or energy storage plant, or other electrical facility.
